(19) United States
(12) Patent Application Publication
(10) Pub. No.: US 2026/0246228 A1
(43) Pub. Date: Aug. 20, 2026

(54) ADDITION OF HEAT TRANSFER PARTICLES IN A VERTICAL CAVITY SURFACE EMITTING LASER (VCSEL)

(71) Applicant: Microchip Technology Incorporated, Chandler, AZ (US)

(72) Inventors: Steve Nagel, Chandler, AZ (US); Bomy Chen, Newark, CA (US)

(73) Assignee: Microchip Technology Incorporated, Chandler, AZ (US)

(21) Appl. No.: 19/182,706

(22) Filed: Apr. 18, 2025

Related U.S. Application Data
(60) Provisional application No. 63/759,805, filed on Feb. 18, 2025.

(51) Int. Cl. H01S 5/024; H01S 5/183

(52) U.S. Cl. CPC H01S 5/02469; H01S 5/183

(57) ABSTRACT

A system and method for the addition of heat transfer particles in a vertical cavity surface emitting laser (VCSEL) are disclosed. The method may include adding a plurality of nanoparticles to a passivation material. The plurality of nanoparticles may have a thermal conductivity of less than 2,200 Watts per meter-Kelvin (W/m-K) at zero degrees Kelvin. The method may also include forming a passivation layer between an active region and a contact in a vertical cavity surface emitting laser. The passivation layer may include the passivation material and the plurality of nanoparticles.

### PRIORITY

This application claims priority to U.S. Provisional Patent Application No. 63/759,805 filed February 18, 2025, the contents of which are hereby incorporated in their entirety.

### TECHNICAL FIELD

The present disclosure relates to vertical cavity surface emitting lasers (VCSEL) and, in particular, to the addition of heat transfer particles in a VCSEL.

### BACKGROUND

A vertical cavity surface emitting laser (VCSEL) is a type of semiconductor laser diode that emits light perpendicular to the surface of a chip, unlike traditional edge-emitting lasers. VCSELs consist of a vertical cavity formed by two highly reflective mirrors, with an active region in between where light is generated. Electrons flow vertically through this structure, and when they recombine in the active region, they emit photons that bounce back and forth between the mirrors, amplifying the light. Eventually, the light escapes through the top surface, creating the laser beam. VCSELs are widely used in applications like data communication, optical sensing, and laser printing due to their efficiency, compact size, and high modulation speeds.

VCSELs generate heat primarily through the process of electrical resistance within the device, where the injected current encounters resistance in the semiconductor layers, causing energy to be dissipated as heat. Additionally, non-radiative recombination of electronics and holes in the active region also contribute to heat generation within the laser cavity. VCSELs generate a significant amount of heat within a small volume due to the increased current flow and optical power, making the VCSEL more susceptible to thermal issues.

The heat generated by VCSELs may impact the performance and lifetime of the VCSEL if not properly managed. Excessive heat may lead to decreased output power, reduced modulation speed, and potential device damage.

### SUMMARY OF THE INVENTION

Aspects provide systems and methods for the addition of heat transfer particles in a vertical cavity surface emitting laser (VCSEL). Examples of the present disclosure may include an apparatus. The apparatus may include a passivation layer in a vertical cavity surface emitting laser. The apparatus may also include a plurality of nanoparticles in the passivation layer. The plurality of nanoparticles may have a thermal conductivity of less than 2,200 Watts per meter-Kelvin (W/m-K) at zero degrees Kelvin.

In combination with any of the above examples, the plurality of nanoparticles may include at least one of aluminum oxide (Al2O3), silicon carbide (SiC), aluminum, aluminum nitride (AlN), boron nitride (BN), silicon dioxide, or diamond.

In combination with any of the above examples, the plurality of nanoparticles may form between approximately 5% and approximately 85% by volume of the passivation layer.

In combination with any of the above examples, the passivation layer may be formed of a polyimide.

In combination with any of the above examples, the passivation layer may be formed of a spin on glass.

In combination with any of the above examples, the apparatus may include a heat chimney extending through the passivation layer. The passivation layer may be to transfer heat from the vertical cavity surface emitting laser to the heat chimney.

In combination with any of the above examples, the heat chimney may be formed of a conductor.

Alone or in combination with any of the above examples, examples of the present disclosure may include a method. The method may include adding a plurality of nanoparticles to a passivation material. The plurality of nanoparticles may have a thermal conductivity of less than 2,200 Watts per meter-Kelvin (W/m-K) at zero degrees Kelvin. The method may also include forming a passivation layer between an active region and a contact in a vertical cavity surface emitting laser. The passivation layer may include the passivation material and the plurality of nanoparticles.

In combination with any of the above examples, the plurality of nanoparticles may include at least one of aluminum oxide (Al2O3), silicon carbide (SiC), aluminum, aluminum nitride (AlN), boron nitride (BN), silicon dioxide, or diamond.

In combination with any of the above examples, the plurality of nanoparticles may form between approximately 5% and approximately 85% by volume of the passivation layer.

In combination with any of the above examples, the passivation layer may be formed of a polyimide.

In combination with any of the above examples, the passivation layer may be formed of a spin on glass.

In combination with any of the above examples, the method may include extending a heat chimney through the passivation layer. The passivation layer is configured to transfer heat from the vertical cavity surface emitting laser to the heat chimney.

In combination with any of the above examples, the heat chimney may be formed of a conductor.

Alone or in combination with any of the above examples, examples of the present disclosure may include a system. The system may include a vertical cavity surface emitting laser. The system may also include a passivation layer in the vertical cavity surface emitting laser. The system may further include a plurality of nanoparticles in the passivation layer. The plurality of nanoparticles may have a thermal conductivity of less than 2,200 Watts per meter-Kelvin (W/m-K) at zero degrees Kelvin.

In combination with any of the above examples, the plurality of nanoparticles may include at least one of aluminum oxide (Al2O3), silicon carbide (SiC), aluminum, aluminum nitride (AlN), boron nitride (BN), silicon dioxide, or diamond.

In combination with any of the above examples, the plurality of nanoparticles may form between approximately 5% and approximately 85% by volume of the passivation layer.

In combination with any of the above examples, the passivation layer may be formed of a polyimide.

In combination with any of the above examples, the passivation layer may be formed of a spin on glass.

In combination with any of the above examples, the system may include a heat chimney extending through the passivation layer. The passivation layer may be to transfer heat from the vertical cavity surface emitting laser to the heat chimney.

### BRIEF DESCRIPTION OF THE DRAWINGS

The figures illustrate examples of systems and methods for the addition of heat transfer particles in a vertical cavity surface emitting laser (VCSEL).

FIG. 1 illustrates a perspective view of a cross section of a VCSEL including heat transfer nanoparticles, according to examples of the present disclosure;

FIG. 2 illustrates a cross-sectional view of a VCSEL including heat transfer nanoparticles in a passivation layer, according to examples of the present disclosure;

FIG. 3 illustrates a method for the addition of heat transfer particles in a vertical cavity surface emitting laser (VCSEL), according to examples of the present disclosure; and

FIG. 4 illustrates a more detailed method for the addition of heat transfer particles in a vertical cavity surface emitting laser (VCSEL), according to examples of the present disclosure.

The reference number for any illustrated element that appears in multiple different figures has the same meaning across the multiple figures, and the mention or discussion herein of any illustrated element in the context of any particular figure also applies to each other figure, if any, in which that same illustrated element is shown.

### DESCRIPTION

According to an aspect of the invention, a system and method for the addition of heat transfer particles in a vertical cavity surface emitting laser (VCSEL) are provided. VCSELs may generate heat during operation. Adequate heat dissipation may maintain the stability of the output (e.g., the wavelength and output power) of the VCSEL because the performance of the VCSEL may be sensitive to temperature. Additionally, heat dissipation may improve the lifetime of the VCSEL because excessive heat may lead to accelerated aging, reduced lifespan, or failure of the VCSEL. Conventional methods for cooling a VCSEL, such as heat sinks or microfluidic cooling, may increase the cost of the VCSEL. The system and methods described herein may improve the performance and longevity of the VCSEL with minimal increase in the cost of the VCSEL by incorporating heat transfer nanoparticles into a passivation layer of the VCSEL to improve the heat dissipation qualities of the VCSEL without adding extra mechanical components or cooling systems to the VCSEL.

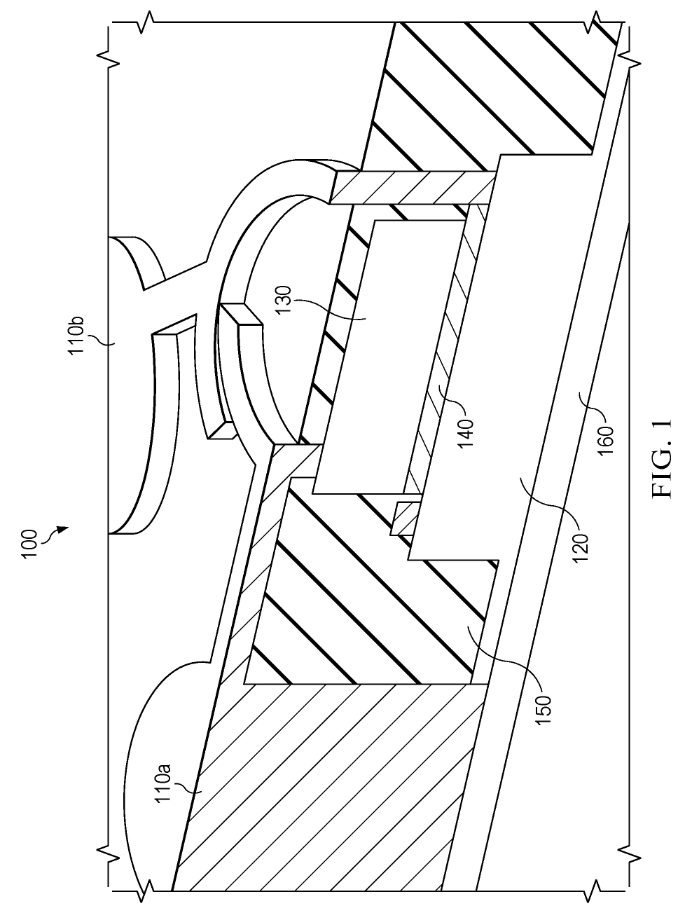

FIG. 1 illustrates a perspective view of a cross section of a VCSEL, according to examples of the present disclosure. VCSEL 100 may include contacts 110, n-type distributed Bragg reflector (DBR) 120, p-type DBR 130, active region 140, and passivation layer 150.

Contacts 110 may provide N-contact and P-contact connections an electrical pathway for current to flow in VCSEL 100. Contacts 110 may be made of any suitable conductive material, such as, but not limited to, gold, titanium, platinum, aluminum, nickel, or any combination thereof. Contacts 110 may also act as a heat chimney to dissipate heat out of VCSEL 100 as described in more detail below.

N-type DBR 120 and p-type DBR 130 may act as mirrors to confine light within the optical cavity of VCSEL 100. By confining light to the optical cavity of VCSEL 100, the light may be amplified by active region 140. N-type DBR 120 and p-type DBR 130 may be parallel to the surface of wafer 160. N-type DBR 120 and p-type DBR 130 may be formed of alternating layers of semiconductor materials with different refractive indices. Therefore, n-type DBR 120 and p-type DBR 130 may create a periodic structure to reflect light at specific wavelengths. N-type DBR 120 and p-type DBR 130 may be made of alloys of gallium arsenide (GaAs), aluminum gallium arsenide (AlₓGa₁₋ₓAs, or simply, AlGaAs), or any other suitable material providing the electrical and thermal conductivity properties for a given application of VCSEL 100.

Active region 140 may be responsible for generating laser light from VCSEL 100 using the process of optical gain. Active region 140 may be formed of multiple-quantum wells (MQWs). Active region 140 may be formed of any suitable material such as, but not limited to, GaAs/AlGaAs and indium gallium arsenide (InGaAs)/AlGaAs.

Passivation layer 150 may serve as a planarization and passivation layer in VCSEL 100. For example, structures forming VCSEL 100 may have a rough and uneven surface. Passivation layer 150 may be applied to create a smooth and planar surface. Passivation layer 150 may then provide a flat surface for providing contact and bonding of other components of VCSEL 100. Additionally, passivation layer 150 may serve as a protective barrier to prevent unwanted oxidation of the internal structures of VCSEL 100. By protecting VCSEL 100 from exposure to the environment and suppressing surface defects, passivation layer 150 may increase the reliability of VCSEL 100.

Passivation layer 150 may also provide heat dissipation in VCSEL 100. Passivation layer 150 may be formed of a material having a low thermal resistance, such as, but not limited to, oxides (e.g., aluminum oxide (Al₂O₃), silicon dioxide (SiO₂), chromium oxide (Cr₂O₃), titanium dioxide (TiO₂), nitrides (e.g., aluminum nitride (AlN), silicon nitride (SiN), polyimide, or a spin-on-glass. The spin-on-glass may be formed of a base material (e.g., silicon dioxide (SiO₂)) suspended in a solvent. In some examples, the spin-on-glass may include a dopant (e.g., boron or phosphorus).

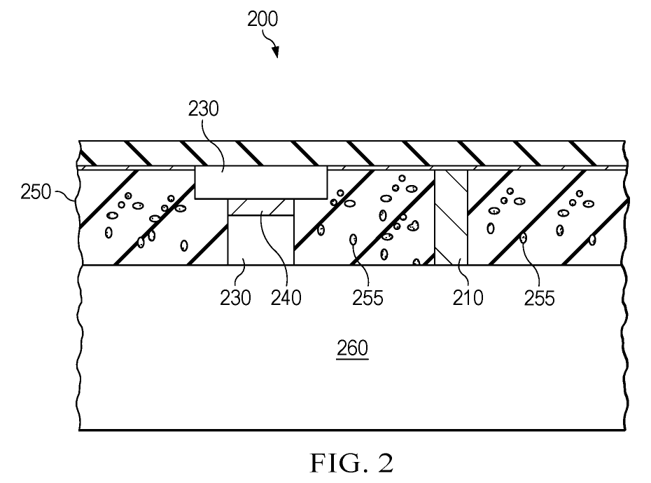

Heat may be transferred away from n-type DBR 120, p-type DBR 130, and active region 140 to contacts 110 via passivation layer 150. The rate of heat transfer from n-type DBR 120, p-type DBR 130, and active region 140 to contacts 110 may be improved by incorporating nanoparticles in passivation layer 150, as described in more detail with respect to FIG. 2.

FIG. 2 illustrates a cross-sectional view of a VCSEL including heat transfer nanoparticles in a passivation layer, according to examples of the present disclosure. VCSEL 200 may be similar to VCSEL 100, shown in FIG. 1, and include contacts 210, n-type distributed Bragg reflector (DBR) 220, p-type DBR 230, active region 240, and passivation layer 250. Contacts 210, n-type distributed Bragg reflector (DBR) 220, p-type DBR 230, active region 240, and passivation layer 250 may be similar to contacts 110, n-type distributed Bragg reflector (DBR) 120, p-type DBR 130, active region 140, and passivation layer 150, respectively, shown in FIG. 1.

Passivation layer 250 may include nanoparticles 255 to enhance the heat transfer properties of passivation layer 250. In some examples, nanoparticles 255 may make up between approximately five percent to approximately eighty-five percent, by volume, of the content of passivation layer 250. The concentration of nanoparticles 255 in passivation layer 250 may depend on factors such as, but not limited to, the material forming nanoparticles 255, the design of VCSEL 200, and the thermal management characteristics of VCSEL 200. Nanoparticles 255 may be distributed through passivation layer 250 in an approximately uniform distribution. The addition of nanoparticles 255 to passivation layer 250 may assist in facilitating the transfer of heat from n-type DBR 220, p-type DBR 230, and active region 240 to contact 210 via passivation layer 250.

Nanoparticles 255 may be made of filler particles having a high thermal conductivity, such as, but not limited to, aluminum oxide (e.g., Al₂O₃), aluminum, aluminum nitride (e.g., AlN), boron nitride (e.g., BN), silicon carbide (SiC), silicon dioxide (SiO₂), diamond, copper, other encapsulated metal fillers, other oxidized metal fillers, or any combination thereof. In some examples, nanoparticles 255 may be formed of silver, gold or carbon nanotubes. The thermal conductivity of nanoparticles 255 may be less than 2,200 Watts per meter-Kelvin (W/m-K) at zero degrees Kelvin.

Nanoparticles 255 may have any suitable shape or size. For example, the size, the shape, or a combination thereof may be varied to adjust the heat transfer properties of passivation layer 250. For example, smaller nanoparticles 255 may provide improved dispersion within passivation layer 250 while larger nanoparticles 255 may create more efficient heat conduction pathways. Nanoparticles 255 may have different shapes, such as, but not limited to, spheres, rods, or platelets to increase the surface area of nanoparticles 255 to increase the heat transfer properties of nanoparticles 255.

To incorporate nanoparticles 255 into the material forming passivation layer 250, nanoparticles 255 may be suspended in the liquid material that will form passivation layer 250. Substrate 260 may then be coated with the liquid material that will form passivation layer 250. Substrate 260 may then be heated such that the solvents may be baked off and passivation layer 250 may harden.

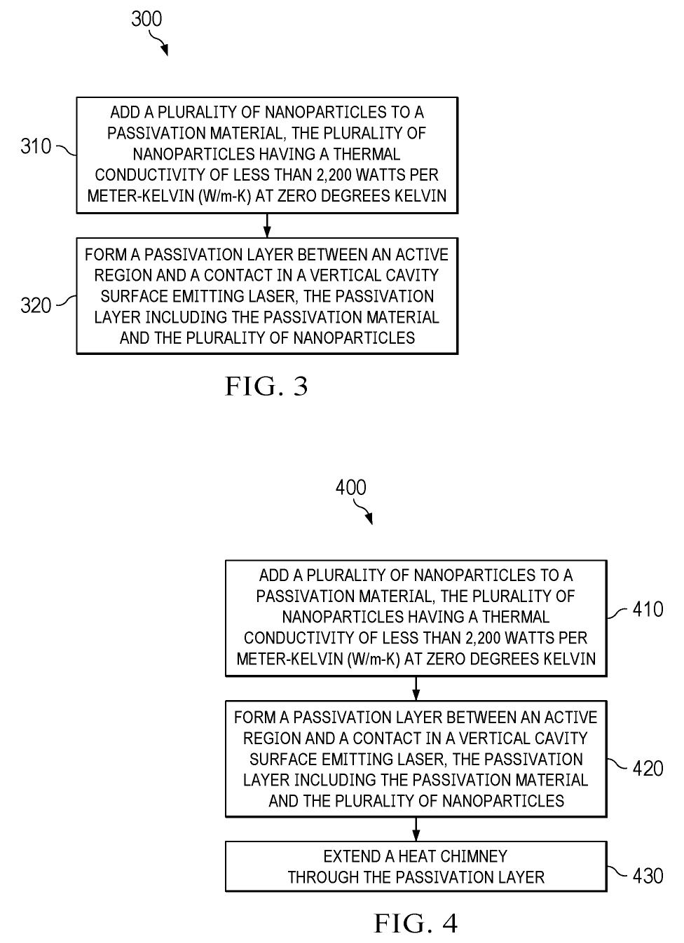

FIG. 3 illustrates a method for the addition of heat transfer particles in a vertical cavity surface emitting laser (VCSEL), according to examples of the present disclosure. Method 300 may be implemented using any suitable semiconductor manufacturing device designed to perform the functions disclosed herein or any other system operable to implement method 300. Although examples have been described above, other variations and examples may be made from this disclosure without departing from the spirit and scope of these disclosed examples.

Method 300 may begin at block 310 where a plurality of nanoparticles may be added to a passivation material. The plurality of nanoparticles may enhance the heat transfer properties of the passivation material. To incorporate the plurality of nanoparticles into the passivation material, the plurality of nanoparticles may be suspended in the liquid passivation material.

The plurality of nanoparticles may have a thermal conductivity of less than 2,200 Watts per meter-Kelvin (W/m-K) at zero degrees Kelvin. The plurality of nanoparticles may be made of filler particles having a high thermal conductivity, such as, but not limited to, aluminum oxide (e.g., Al₂O₃), aluminum, aluminum nitride (e.g., AlN), boron nitride (e.g., BN), silicon carbide (SiC), silicon dioxide (SiO₂), diamond, copper, other encapsulated metal fillers, other oxidized metal fillers, or any combination thereof. In some examples, the plurality of nanoparticles may be formed of silver, gold or carbon nanotubes.

In some examples, the plurality of nanoparticles may make up between approximately five percent to approximately eighty-five percent, by volume, of the content of the passivation material. The concentration of the plurality of nanoparticles in the passivation material may depend on factors such as, but not limited to, the material forming the plurality of nanoparticles, the design of the VCSEL, and the thermal management characteristics of the VCSEL.

The plurality of nanoparticles may have any suitable shape or size. For example, the size, the shape, or a combination thereof may be varied to adjust the heat transfer properties of the passivation material. For example, smaller nanoparticles may provide improved dispersion within the passivation material while larger nanoparticles may create more efficient heat conduction pathways. The plurality of nanoparticles may have different shapes, such as, but not limited to, spheres, rods, or platelets to increase the surface area of the plurality of nanoparticles to increase the heat transfer properties of the plurality of nanoparticles.

At block 320, a passivation layer may be formed between an active region and a contact in a VCSEL. The passivation layer may include the passivation material and the plurality of nanoparticles. A substrate may be coated with the passivation material, including the plurality of nanoparticles. The substrate may then be heated such that the solvents may be baked off and the passivation material may harden to form the passivation layer between the active region and the contact in a VCSEL.

Although FIG. 3 discloses a particular number of operations related to method 300, method 300 may be executed with greater or fewer operations than those depicted in FIG. 3. In addition, although FIG. 3 discloses a certain order of operations to be taken with respect to method 300, the operations comprising method 300 may be completed in any suitable order.

FIG. 4 illustrates a more detailed method for the addition of heat transfer particles in a vertical cavity surface emitting laser (VCSEL), according to examples of the present disclosure. Method 400 may be implemented using any suitable semiconductor manufacturing device designed to perform the functions disclosed herein or any other system operable to implement method 400. Although examples have been described above, other variations and examples may be made from this disclosure without departing from the spirit and scope of these disclosed examples.

Method 400 may begin at block 410 where a plurality of nanoparticles may be added to a passivation material. The plurality of nanoparticles may enhance the heat transfer properties of the passivation material. To incorporate the plurality of nanoparticles into the passivation material, the plurality of nanoparticles may be suspended in the liquid passivation material.

The plurality of nanoparticles may have a thermal conductivity of less than 2,200 Watts per meter-Kelvin (W/m-K) at zero degrees Kelvin. The plurality of nanoparticles may be made of filler particles having a high thermal conductivity, such as, but not limited to, aluminum oxide (e.g., Al₂O₃), aluminum, aluminum nitride (e.g., AlN), boron nitride (e.g., BN), silicon carbide (SiC), silicon dioxide (SiO₂), diamond, copper, other encapsulated metal fillers, other oxidized metal fillers, or any combination thereof. In some examples, the plurality of nanoparticles may be formed of silver, gold or carbon nanotubes.

In some examples, the plurality of nanoparticles may make up between approximately five percent to approximately eighty-five percent, by volume, of the content of the passivation material. The concentration of the plurality of nanoparticles in the passivation material may depend on factors such as, but not limited to, the material forming the plurality of nanoparticles, the design of the VCSEL, and the thermal management characteristics of the VCSEL.

The plurality of nanoparticles may have any suitable shape or size. For example, the size, the shape, or a combination thereof may be varied to adjust the heat transfer properties of the passivation material. For example, smaller nanoparticles may provide improved dispersion within the passivation material while larger nanoparticles may create more efficient heat conduction pathways. The plurality of nanoparticles may have different shapes, such as, but not limited to, spheres, rods, or platelets to increase the surface area of the plurality of nanoparticles to increase the heat transfer properties of the plurality of nanoparticles.

At block 420, a passivation layer may be formed between an active region and a contact in a VCSEL. The passivation layer may include the passivation material and the plurality of nanoparticles. A substrate may be coated with the passivation material, including the plurality of nanoparticles. The substrate may then be heated such that the solvents may be baked off and the passivation material may harden to form the passivation layer between the active region and the contact in a VCSEL.

At block 430, a heat chimney may be extended through the passivation layer. The heat chimney may be a contact of the VCSEL that provide an electrical pathway for current to flow in the VCSEL (e.g., contacts 110 shown in FIG. 1). Additionally, the heat chimney may allow heat to dissipate out of the VCSEL. Specifically, heat may be transferred from the active region of the VCSEL to the heat chimney through the passivation layer and out of the VCSEL through the heat chimney. The heat chimney may be made of any suitable conductor, such as, but not limited to, gold, titanium, platinum, aluminum, nickel, or any combination thereof.

Although FIG. 4 discloses a particular number of operations related to method 400, method 400 may be executed with greater or fewer operations than those depicted in FIG. 4. In addition, although FIG. 4 discloses a certain order of operations to be taken with respect to method 400, the operations comprising method 400 may be completed in any suitable order.

Although examples have been described above, other variations and examples may be made from this disclosure without departing from the spirit and scope of these disclosed examples.

1. An apparatus, comprising:
a passivation layer in a vertical cavity surface emitting laser; and
a plurality of nanoparticles in the passivation layer, the plurality of nanoparticles having a thermal conductivity of less than 2,200 Watts per meter-Kelvin (W/m-K) at zero degrees Kelvin.

2. The apparatus of claim 1, wherein the plurality of nanoparticles include at least one of aluminum oxide (Al₂O₃), silicon carbide (SiC), aluminum, aluminum nitride (AlN), boron nitride (BN), silicon dioxide, or diamond.

3. The apparatus of claim 1, wherein the plurality of nanoparticles form between approximately 5% and approximately 85% by volume of the passivation layer.

4. The apparatus of claim 1, wherein the passivation layer is formed of a polyimide.

5. The apparatus of claim 1, wherein the passivation layer is formed of a spin on glass.

6. The apparatus of claim 1, comprising a heat chimney extending through the passivation layer;
wherein the passivation layer is to transfer heat from the vertical cavity surface emitting laser to the heat chimney.

7. The apparatus of claim 6, wherein the heat chimney is formed of a conductor.

8. A method, comprising:
adding a plurality of nanoparticles to a passivation material, the plurality of nanoparticles having a thermal conductivity of less than 2,200 Watts per meter-Kelvin (W/m-K) at zero degrees Kelvin; and
forming a passivation layer between an active region and a contact in a vertical cavity surface emitting laser, the passivation layer including the passivation material and the plurality of nanoparticles.

9. The method of claim 8, wherein the plurality of nanoparticles include at least one of aluminum oxide (Al₂O₃), silicon carbide (SiC), aluminum, aluminum nitride (AlN), boron nitride (BN), silicon dioxide, or diamond.

10. The method of claim 8, wherein the plurality of nanoparticles form between approximately 5% and approximately 85% by volume of the passivation layer.

11. The method of claim 8, wherein the passivation layer is formed of a polyimide.

12. The method of claim 8, wherein the passivation layer is formed of a spin on glass.

13. The method of claim 8, comprising extending a heat chimney through the passivation layer;
wherein the passivation layer is configured to transfer heat from the vertical cavity surface emitting laser to the heat chimney.

14. The method of claim 13, wherein the heat chimney is formed of a conductor.

15. A system, comprising:
a vertical cavity surface emitting laser;
a passivation layer in the vertical cavity surface emitting laser; and
a plurality of nanoparticles in the passivation layer, the plurality of nanoparticles having a thermal conductivity of less than 2,200 Watts per meter-Kelvin (W/m-K) at zero degrees Kelvin.

16. The system of claim 15, wherein the plurality of nanoparticles include at least one of aluminum oxide (Al₂O₃), silicon carbide (SiC), aluminum, aluminum nitride (AlN), boron nitride (BN), silicon dioxide, or diamond.

17. The system of claim 15, wherein the plurality of nanoparticles form between approximately 5% and approximately 85% by volume of the passivation layer.

18. The system of claim 15, wherein the passivation layer is formed of a polyimide.

19. The system of claim 15, wherein the passivation layer is formed of a spin on glass.

20. The system of claim 15, comprising a heat chimney extending through the passivation layer;
wherein the passivation layer is to transfer heat from the vertical cavity surface emitting laser to the heat chimney.
